(19) United States
(12) Patent Application Publication
(10) Pub. No.: US 2011/0236802 A1
(43) Pub. Date: Sep. 29, 2011

(54) METHOD FOR FABRICATING THE HOLOGRAPHIC GRATING

(75) Inventors: Chaoming Li, Suzhou (CN); Xinrong Chen, Suzhou (CN); Junhua Pan, Suzhou (CN); Jianhong Wu, Suzhou (CN); Zuyuan Hu, Suzhou (CN)

(73) Assignee: SOOCHOW UNIVERSITY, Suzhou (CN)

(21) Appl. No.: 13/043,265

(22) Filed: Mar. 8, 2011

(30) Foreign Application Priority Data
Mar. 25, 2010 (CN) 201010142320.2

(51) Int. Cl. G03F 7/00

(52) U.S. Cl. 430/2

(57) ABSTRACT

This invention discloses a method for fabricating a holographic grating with low diffractive wave aberrations on a substrate with aberrations. Forming a interference recording field from two coherent beams, where one is a parallel beam and the other is a beam whose wave-front can be controlled, recording the holographic field on the substrate with aberrations, fabricating the holographic grating with low diffractive wave aberrations, setting a deformable minor into one of the coherent recording beams, and controlling the shape of said deformable minor so as to obtain a compensated interference recording field. Expose the recoding plate under the holographic interference recording field which has been adjusted by the deformable minor to record the grating. After developing, the fabrication of holographic grating with low diffractive wave aberration is finished.

### CROSS-REFERENCES TO RELATED APPLICATIONS

This application claims priority from Chinese Application No. 201010142320.2, filed Mar. 25, 2010 incorporated by reference in its entirety.

This invention relates to a method for fabricating a diffractive element, and more particularly to a method for fabricating a low diffractive wave aberration holographic grating on a large scale substrate that contains aberrations.

### BACKGROUND

A large scale plane diffractive grating with one dimension is a key element in some high technology projects such as a inertial confined fusion laser system. In order to meet the requirement of the high energy, the grating should be provided with large size and low diffractive aberration. The diffractive aberrations of the grating are related to the whole holographic optical recording system. It comprises of two parts. One is the holographic optical recording system, and the other is the substrate. The holographic optical recording system is used to produce an interference field for recording holographic grating. The photographic material is coated on the substrate. Through the interference exposure, the interference fringe is recorded into the photographic material and after developing the diffractive grating emerges. The holographic technology is a very important way to fabricating the large scale grating, and the diffractive wave aberrations of the grating are defined by the aberrations in the holographic recording optical system and the substrate.

In the previous art, it has been very difficult to fabricate the large scale substrate with low aberrations, especially for the substrate whose aperture is over 300 mm. For a substrate that is needed to deposit the dielectric stack film, after depositing, the aberration of the substrate will be changed. This leads to an overwhelming difficulty in fabricating holographic grating with low diffractive wave aberrations. Under the state of art in the optical fabrication, film deposition and holographic recording, it is very difficult to fabricate the meter scale grating with diffractive wave aberrations of less than 0.1λ.

### SUMMARY OF THE INVENTION

The object of the present invention is to provide a method of accomplishing the holographic grating with low diffractive wave aberrations on a substrate that contains aberrations. This object is achieved according to the technical solution described below:

Establishing the holographic recording optical system is illustrated in FIG. 1. The recording field is made of two coherent beams. One is a parallel beam and the other is a beam whose wave-front can be controlled. The holographic grating with low diffractive wave aberration can be fabricated on the substrate that contains aberrations. A deformable mirror is set into the optical path in order to obtain a beam whose wave-front can be controlled. The fabrication process comprising:

(1) Using an interferometer to measure the surface shape of the substrate that is used to record the holographic grating, so as to obtain the data of aberration distribution of the substrate; coating the photographic material on the large scale substrate, then a recording plate to record the holographic grating.

(2) According to the aberration distribution data of the substrate and the formula of the diffractive wave aberration of holographic grating, the target wave-front that contains a certain aberration that can make the diffractive wave aberration of the grating null is deduced. At the same time, the corresponding wave-front of the recording beam and the data of surface shape of the deformable mirror are calculated.

(3) In order to obtain the target wave-front defined in step (2), the controller of the deformable mirror is adjusted to change the surface shape of the minor and its wave-front is measured with the interferometer on-line. When it happens that the wave-front measured by the interferometer is in accord with the target wave-front, the adjusting procedure is finished. Consequently, the required holographic recording field is also obtained. Said deformable minor, said controller of the deformable mirror, and said interferometer make up a controllable and measurable closed-loop system that provides a technical means of obtaining a controllable wave-front of beam and a controllable holographic recording field.

(4) Exposing the recording plate under said controllable holographic recording field, and after developing, the fabrication of the grating with low diffractive wave aberration is accomplished.

The principle of the above-mentioned method is as follows:

The diffractive wave aberration is derived from the holographic fabrication system of grating. The holographic fabrication system of grating is comprised of two parts. One is the holographic recording optical system that is used to produce the interference field. The other is the recording plate that is used to record the interference fringes. The diffractive wave aberration is a synthesis aberration that consists of the aberration of the holographic optical system and the aberration of the recording plate. The mathematical expression of the diffractive wave aberration, that is W, can be represented by:

W=f(w₁,w₂) (1)

Where w₂ represents the aberration of the recording plat, w₁ represents the aberration of the holographic recording optical system and also a representation of the wave-front of the holographic interference recording field. w₁ is defined by the wave-front of two recording beams, which is presented:

w₁=φ₁−φ₂ (2)

Where φ₁ is the wave-front of recording beam 1, φ₂ is the wave-front of recording beam 2.

Formula (1) shows that: if w₂ is not equal to zero, by changing the value of w₁, the value of W can be compensated to zero.

The principle of aberration compensation is as follows:

Two coherent parallel beams with null a wave aberration will form equidistant parallel straight fringes when they are interfering in the space. When recording these straight fringes with recording plate, a grating with equidistant parallel straight grooves is obtained. If there are aberrations in the interference beam, the grooves of the grating fabricating with two interference beams that contain the aberrations will take on some bending. The groove will have a lateral displacement (illustrated in FIG. 3). The quantity of the lateral displacement OE (expressed as x) is proportion to the wave aberration of the recording beams. Assuming that h represents the shape value of the recording plate (shown in FIG. 3, where h=BE), the parallel beam RR′ is incident upon the grating from the air. The incident angle is expressed by α. The diffractive angle of reflective diffraction beam SS′ is expressed by β. The optical path difference Δl between RR′ and SS′ is given by:

Δl=AB−BC (3)

The correspondent diffractive wave aberration is defined as:

$$W = \frac{Δ l}{λ} \qquad ( 4 )$$

Where λ is the wavelength of measuring laser. The incident angle α and the diffractive angle β are satisfied with the grating equation:

d(sin α+sin β)=mλ (5)

Where d is the constant of the grating and m represents the order of diffraction. From formula (3), the diffractive wave aberration will be zero if AB=BC. And then, the quantity of lateral displacement x and the shape value of the recording plate h will be followed as:

$$x = h \cdot ctg ( \frac{α + β}{2} ) \qquad ( 6 )$$

Let these two beams (whose wavelength is λ₀) be symmetrically incidence upon the recording plate with the incident angle θ₀, the relationship between the lateral displacement x and the wave aberration of the holographic recording optical system w₁ is:

$${w}_{1} = \frac{x}{{λ}_{0} / ( 2 sin {ϑ}_{0} )} \qquad ( 7 )$$

In this method, the wave aberration of the holographic recording optical system is provided by the deformable mirror. The included angle θ is formed by the primary ray of the recording beam and the normal of the deformable minor. Thus the relationship between the strain quantity of the mirror s and the wave aberration of the holographic recording optical system w₁ is:

$${w}_{1} = \frac{2 s cos ϑ}{{λ}_{0}} \qquad ( 8 )$$

From formula (6) to (8), it can be deduced that when the strain quantity of the mirror s and the shape value of the recording plate h are satisfied in the following expression:

$$s = h \cdot \frac{sin {ϑ}_{0}}{cos ϑ} \cdot ctg ( \frac{α + β}{2} ) \qquad ( 9 )$$

The diffractive wave aberration of the grating will be zero. That is to say, the compensation of aberration will be accomplished.

In above technical solution, the holographic recording optical system that contains a deformable mirror in one optical path forms a controllable and interactive system. It is completely different from the ordinary holographic recording optical system. Because the wave-front of the holographic interference field can be adjusted, it can afford a controllable interference field with the wave aberration w₁. Thus, it provides the technical way to fabricate the holographic grating with low diffractive wave aberration.

The mechanism of controllable the holographic interference field is as follows:

The deformable minor is composed of a minor and a plurality of actuators that are distributed behind the mirror. It is a phase device. By regulating the actuators, the minor surface shape will be changed. After the ray trace, while a beam is reflected by the deformable mirror, due to the change of the mirror surface shape, an additional optical path difference will emerge and the phase of the reflective wave-front will consequently change. If this reflective beam is one of the two coherent beams, the holographic interference field will also change. The control of the holographic interference field is implemented by regulating the actuators of the deformable mirror.

Using the above technical solution, this invention has the following advantages compared with the prior technologies:

1. In this invention, a deformable mirror is placed into the holographic recording optical system. The deformable minor is inserted into the divergence optical beam, the size of the deformable mirror may be far less than the size of the recording beam. So the cost and difficulty in fabricating the deformable mirror are reduced greatly. Locating an interferometer in the normal direction of the deformable mirror can not only measure its surface shape, but also can allow the interferometer not to obstruct the holographic recording beams. The adjusting of the holographic interference field is implemented by the deformable minor. The aberration compensation to the substrate of grating is implemented by using the controllable wave-front of the holographic interference field and then the holographic grating with low diffractive wave aberration is accomplished.

2. As the scale of the optical substrate is increased, the cost and the difficulty of fabricating the optical substrate with less than 0.1λ surface shape are consequently increased. If the surface shape of the substrate is not ideal and has aberrations, when the grating is recorded on this kind of substrate, the diffractive wave aberration of grating cannot meet to the actual requirement. This invention enlarges the technological parameter range of the substrate surface shape and decreases the cost and the difficulty of fabrication the optical substrate with large scale. And meanwhile decreases the cost and the difficulty of fabrication of the large scale grating with low diffractive wave aberrations.

### BRIEF DESCRIPTION OF THE DRAWINGS

FIG. 1 illustrates the schematic diagram of the set-up of fabricating grating with low diffractive wave aberration in Example 1.

FIG. 2 illustrates the frame of technology route of fabricating grating with low diffractive wave aberration in Example 1.

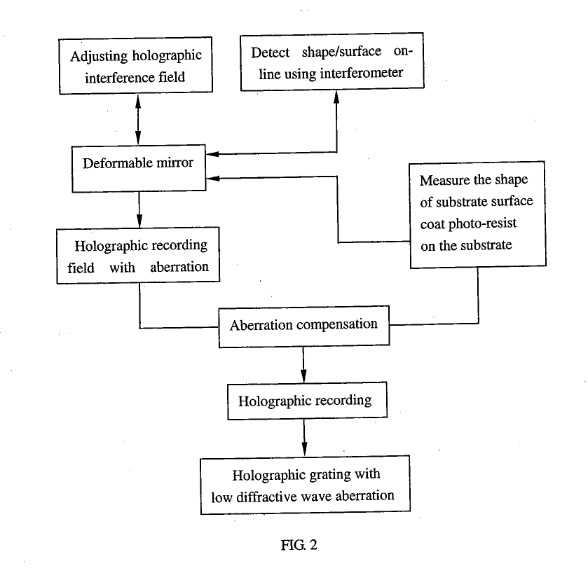

FIG. 3 illustrates the schematic diagram of the principle of aberration compensation.

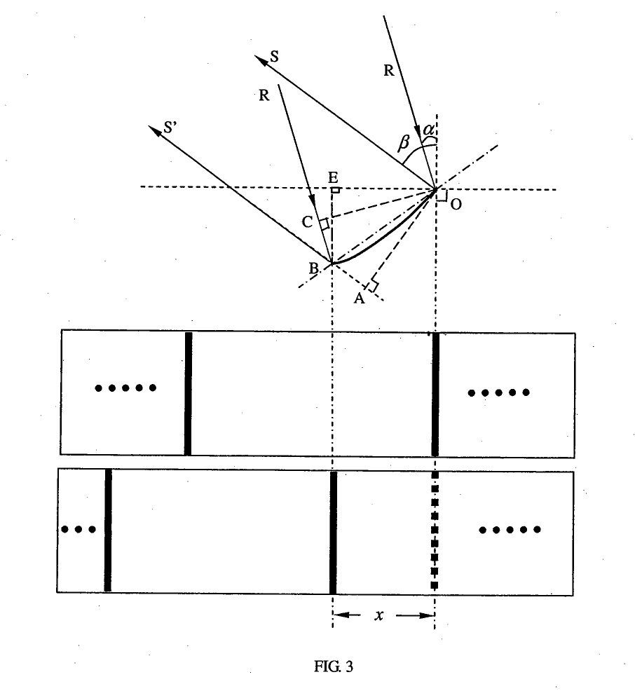

### DETAILED DESCRIPTION OF THE PREFERRED EMBODIMENTS

This invention will be best understood with reference to the figures and following description of example embodiments:

### Example 1

The comparison of the diffractive wave aberration between the two fabricating large scale grating methods, that is, ordinary holographic recording method and the method mentioned in this invention, is shown as follows.

Assume the fabricating of a one dimension grating with a scale of 200 mm×400 mm and spatial frequency of 1740 lp/mm by an ordinary holographic recording method. The wavelength of two parallel recording beams is 413.1 nm. The incident angle of these two recording beams is 21°. Suppose that the aberration of these two recording beams is null and the surface shape of the substrate coated with photo-resist (i.e. recording plate) is 0.5λ. Here λ is the measuring wavelength and λ=632.8 nm. The recording plate is exposed and the holographic grating is recorded. When a parallel beam incidence this grating at the Littrow incident angle, the diffractive wave aberration of the grating is 0.84λ calculated by the formula of diffractive wave aberration of holographic grating.

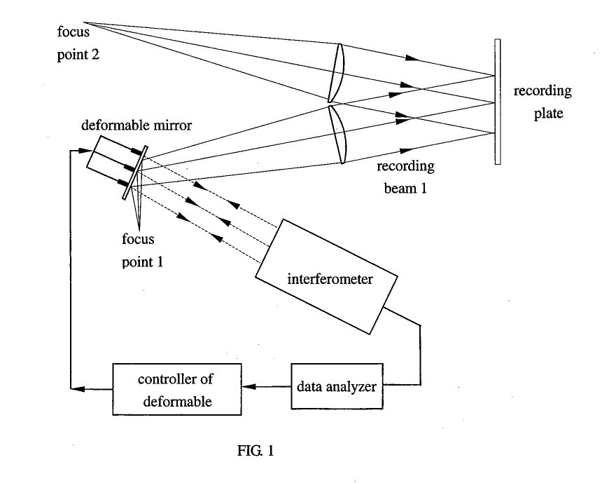

Assumed that the fabricating the one dimension grating with the scale of 200 mm×400 mm and spatial frequency of 1740 lp/mm on the substrate whose surface shape is imperfect using the method described in this invention. The holographic optical recording interference field is formed by two coherent beams (i.e. optical path 1 and optical path 2). The deformable mirror is located into the divergence optical beam 1 (see the optical setup in FIG. 1). The interferometer is placed in the normal direction of the deformable mirror to measure its surface shape. The recording plate is exposed with its imperfect surface shape and the holographic grating is fabricated. A parallel beam incidence this grating at the Littrow incident angle, the data of wave aberration distribution of the 1st order diffraction wave-front of the grating is obtained from the interferometer.

The procedures of fabricating holographic grating with low diffractive wave aberration are as follows:

Measure the surface shape of the substrate that is used to fabricate the holographic grating using the large scale interferometer in order to obtain its aberration distribution. Then coat the homogeneous photo-resist on the substrate with uniform thickness to make up the recording plate.

Establish the holographic optical recording system according to FIG. 1. Adjust the optical paths. Ensure both incident angles of recording beam 1 and recording beam 2 to be 21°. Put the interferometer in the normal direction of the deformable minor. The included angle formed by the primary ray of the recording beam and the normal of the deformable mirror is also 21°.

According to the distribution of aberration of the substrate and the formula of the diffractive wave aberration of holographic grating, calculate the optical path difference of the rays in the holographic system in order to obtain the required wave-front (i.e. w₁) that can compensate the substrate aberration (i.e. w₂) and, at the same time, deduce the surface shape of the deformable mirror corresponding to w₁. After calculation, the maximum strain quantity of the deformable mirror is 0.32 (measuring wavelength is 632.8 nm).

Measure the surface shape of the deformable minor using the interferometer. Adjust the actuators of the deformable mirror until its surface shape meets the requirement in step 3.

After exposure and develop, a holographic grating with low diffractive wave aberration is accomplished.

The diffractive wave aberration of the holographic grating that is fabricated according to the above mentioned procedures is zero theoretically. Comparing with the holographic grating which is fabricated by the ordinary method, the diffractive wave aberration has been significantly decreased.

We claim:

1. A method for fabricating a holographic grating, forming a interference recording field from two coherent beams, where one is a parallel beam and the other is a beam whose wave-front can be controlled, recording the holographic field on the substrate with aberrations, fabricating the holographic grating with low diffractive wave aberrations, by setting a deformable mirror into one of the coherent recording beams, so as to form a beam with a controllable wave-front, detecting the shape of said deformable mirror with a interferometer, controlling and adjusting the shape of said deformable mirror with the controller, so as to control the wave-front of the recording beam, obtaining a controllable interference recording field,
said method comprising,
(1) detecting a surface shape of a substrate of the holographic grating with a interferometer, to obtain data of aberration distribution of the substrate; coating a photoresist on the substrate and a recording plate to record the holographic grating;
(2) according to the data of aberration distribution of the substrate, deducing a required wave-front of an interference recording field when the diffractive wave aberration of the grating is null, and deducing the corresponding wave-front of the recording beam and the data of surface shape of the deformable mirror;
(3) detecting the surface shape of the deformable minor with a interferometer, so as to obtain data of said surface shape, and adjusting a controller of the deformable minor until the surface shape of the deformable minor is equal to the target wave-front; said deformable mirror, said controller of the deformable mirror and said interferometer forming a closed-loop system which can implement control and measurement of the interference recording field; and
(4) after finishing adjustment of the deformable mirror, obtain a required interference recording field that contains a certain aberration that can compensate the aberration of the substrate, exposing the recording plate under said interference recording field obtained by adjusting said deformable minor in step (3), recording the holographic grating, after developing, to achieve the holographic grating with low diffractive wave aberrations.
